(19) United States
(12) Patent Application Publication
(10) Pub. No.: US 2016/0081206 A1
(43) Pub. Date: Mar. 17, 2016

(54) DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventor: Wenhao Zhang, Beijing (CN)

(21) Appl. No.: 14/742,620

(22) Filed: Jun. 17, 2015

(30) Foreign Application Priority Data
Sep. 11, 2014 (CN) 201410461490.5

(51) Int. Cl. H05K 5/02; F21V 9/08; G02B 5/20; H05K 5/00

(52) U.S. Cl. CPC H05K 5/02; H05K 5/0017; F21V 9/08; G02B 5/201; F21Y 2105/001

(57) ABSTRACT

The invention discloses a display device, relates to the field of display product, and aims to provide a frameless display product with improved display performance. The display device comprises a fixing substrate and a display substrate. The fixing substrate comprises a main body extending in a horizontal direction and first bending structures arranged at both sides of the main body. The display substrate comprises a main body extending in the horizontal direction and second bending structures arranged at both sides of the main body and matching the first bending structures. The second bending structures are located at outer sides of the first bending structures, and the fixing substrate and the display substrate are engaged with each other and assembled in a sealed manner by means of the first and second bending structures. The invention is primarily applied for producing a small size display apparatus. (FIG. 3)

### RELATED APPLICATION(S)

The present application claims the benefit of Chinese Patent Application No. 201410461490.5, filed Sep. 11, 2014, the entire disclosure of which is incorporated herein by reference.

### FIELD OF THE INVENTION

The present invention relates to a technical field of a display product, and particularly to a display device.

### BACKGROUND ART

As an output means of electronic products, a display device is considered seriously by a user in terms of its performance and appearance.

Currently, display devices on market have a planar or curved screen around which frames are generally provided for encapsulating components inside the electronic products. However, due to development of science and technology as well as the user's pursuit of fashion, a conceptual product, i.e., a display device without frames at both sides in a horizontal direction has been proposed. In such a display device, the panel is frameless at both sides in the horizontal direction, so that all area of the planar surface in the horizontal direction can be formed into a display area, a more broad visual effect can be obtained, and the operational performance of the display device can be improved. In addition, the frameless display device can further be used for jointing with a large screen product to realize stereoscopic projection.

Therefore, there is an urgent in the art to provide a frameless display device.

### SUMMARY

The present invention provides a display device, so as to provide a frameless display product with improved display performance.

To this end, the present invention adopts the following technical solutions.

A display device comprises a fixing substrate and a display substrate, wherein the fixing substrate comprises a main body extending in a horizontal direction and first bending structures arranged at both sides of the main body, the display substrate comprises a main body extending in a horizontal direction and second bending structures arranged at both sides of the main body and matching the first bending structures, the second bending structures are located at outer sides of the first bending structures, and the fixing substrate and the display substrate are engaged with each other and assembled in a sealed manner by means of the first and second bending structures.

Preferably, a frame sealant can be arranged between the first and second bending structures.

Preferably, the second bending structures of the display substrate may comprise a side display area.

Preferably, a first light emitting layer can be arranged on surfaces of the main body and the first bending structures of the fixing substrate, and the first light emitting layer may comprise a plurality of color light emitting diodes.

Preferably, a first light filtering layer can be arranged on surfaces of the main body and the second bending structures of the display substrate, and the first light filtering layer can cooperate with the first light emitting layer and be used to modify wavelength of light emitted from the first light emitting layer.

Preferably, a second light emitting layer can be arranged on surfaces of the main body and the first bending structures of the fixing substrate, the second light emitting layer may comprise a plurality of white light emitting diodes, and a second light filtering layer, which cooperates with the second light emitting layer, can be arranged on surfaces of the main body and the second bending structures of the display substrate.

Preferably, the main body and the first bending structures of the fixing substrate can be arranged to be perpendicular to each other, and corner portions between the main body and the first bending structures of the fixing substrate can be arc-shaped chamfers; the main body and the second bending structures of the display substrate can be arranged to be perpendicular to each other, and corner portions between the main body and the second bending structures of the display substrate can be arc-shaped chamfers.

Preferably, corner portions between the main body and the first bending structures of the fixing substrate can be cute angles, and corner portions between the main body and the second bending structures of the display substrate can be cute angles.

Preferably, the fixing substrate and the display substrate can be glass substrates or plastic substrates of high transmittance.

Preferably, the fixing substrate can be an array substrate, and the display substrate can be a color film substrate.

In an embodiment of the present invention, as shown in FIG. 1 and FIG. 2, a display device comprises a fixing substrate and a display substrate which are engaged with each other and assembled in a sealed manner. The fixing substrate and the display substrate comprise first and second bending structures at both sides of a main body extending in a horizontal direction (in a direction shown by an arrow in FIG. 2). The second bending structures match the first bending structures, the second bending structures are located at outer sides of the first bending structures, and the fixing substrate and the display substrate are engaged with each other and assembled in a sealed manner by means of the first and second bending structures. According to the present invention, by means of the first and second bending structures at both sides of the main body which extends the horizontal direction, the fixing substrate and the display substrate are engaged with each other and assembled in a sealed manner, thus providing a display device without frames in the horizontal direction in a simple manner.

A frame sealant can be arranged between the first and second bending structures. Based on this analysis, in the display device according to an embodiment of the present invention, the frame sealant is applied to assemble the first bending structures of the fixing substrate and the second bending structures of the display substrate in a sealed manner. Thus, there is no need to provide frames at both sides of the display device in the horizontal direction for sealing and assembling. In this way, all area of the display device in the horizontal direction can be formed into a display area (as shown by a region AA indicated by thick lines in FIG. 1). Further, a more broad visual effect is obtained, and the operational and display performance of the display device is improved.

The (frameless) display device of the present invention can be further used for jointing with a large screen product, so that display areas of individual apparatus fit closely together to enable a seamless connection. In this way, smooth transitions between the displayed pictures and a function of stereoscopic projection can be realized.

### BRIEF DESCRIPTION OF DRAWINGS

FIG. 1 is a schematic view of a display device in an embodiment of the present invention;

FIG. 2 is a cross-sectional view of a display device in an embodiment of the present invention;

FIG. 3 is a cross-sectional view of another display device in an embodiment of the present invention;

FIG. 4 is a cross-sectional view of a display device in an embodiment of the present invention;

FIG. 5 is a cross-sectional view of another display device in an embodiment of the present invention;

FIG. 6 a cross-sectional view of a further display device in an embodiment of the present invention; and

FIG. 7 is an enlarged view of a region in FIG. 5 indicated by a dashed circle.

### DETAILED DESCRIPTION OF EMBODIMENTS

A display device in an embodiment of the present invention will be described in detail hereinafter by reference to the accompanying drawings.

The following reference numerals are adopted in the drawings: AA—display area, 1—fixing substrate, 11—first bending structure, 2—display substrate, 21—second bending structure, 22—side display area, 3—frame sealant, 41—first light emitting layer, 411—color light emitting diode, 42—second light emitting layer, 422—white light emitting diode, 51—first filtering layer, 52—second filtering layer, 6, 6′—corner portion.

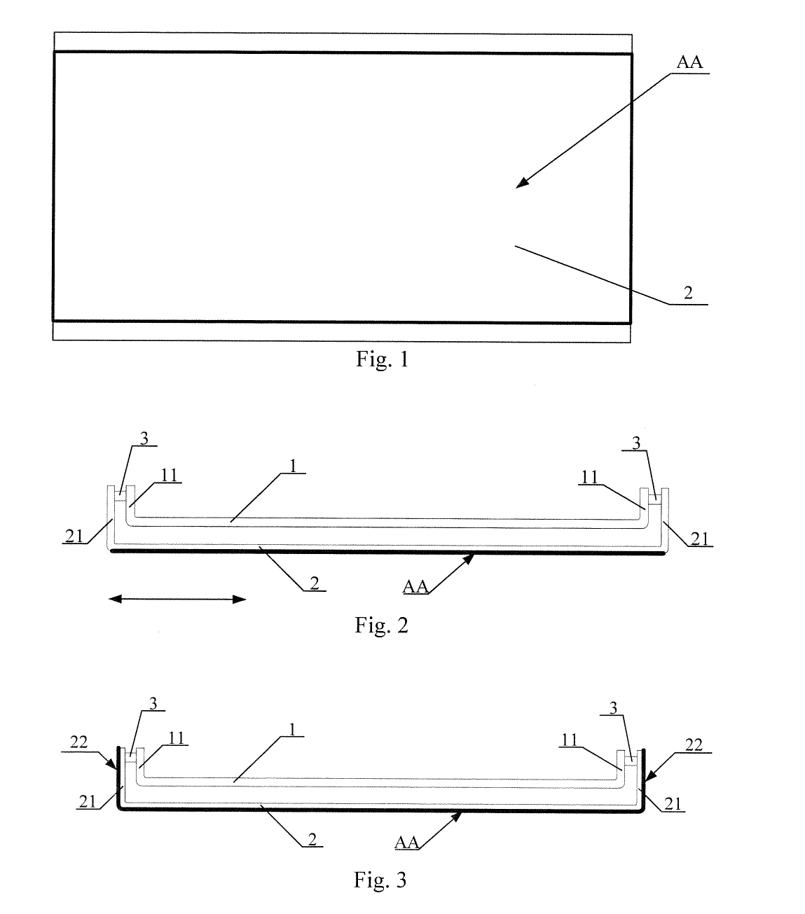

In an embodiment of the present invention, as shown in FIG. 1 and FIG. 2, a display device comprises a fixing substrate 1 and a display substrate 2. The fixing substrate 1 comprises a main body extending in a horizontal direction (in a direction shown by an arrow in FIG. 2) and first bending structures 11 arranged at both sides of the main body. The display substrate 2 comprises a main body extending in a horizontal direction and second bending structures 21 arranged at both sides of the main body and match the first bending structures 11. The second bending structures 21 are located at outer sides of the first bending structures 11. The fixing substrate 1 and the display substrate 2 are engaged with each other and assembled in a sealed manner by means of the first and second bending structures 11, 21.

A frame sealant 3 is arranged between the first bending structures 11 and the second bending structures 21.

In the embodiment shown in FIG. 1 and FIG. 2, the display device comprises the fixing substrate and the display substrate. The fixing substrate and the display substrate comprise the first and second bending structures at both sides of the main body extending in the horizontal direction, and the second bending structures are located at outer sides of the first bending structures. The fixing substrate and the display substrate are engaged with each other and assembled in a sealed manner. According to this embodiment, a display device without frames in the horizontal direction can be realized in a simple manner.

A frame sealant can be arranged between the first and second bending structures. Based on this analysis, in the display device according to an embodiment of the present invention, the frame sealant is applied to assemble the first bending structures of the fixing substrate and the second bending structures of the display substrate in a sealed manner. Thus, there is no need to provide frames at both sides of the display device in the horizontal direction for sealing and assembling. In this way, all area of the display device in the horizontal direction can be formed into a display area (as shown by a region AA indicated by thick lines in FIG. 1). Further, a more broad visual effect is obtained, and the operational and display performance of the display device is improved. In addition, the (frameless) display device of this embodiment can be further used for jointing with a large screen product, so that display areas of individual apparatus fit closely together to enable a seamless connection. In this way, smooth transitions between the displayed frames and a function of stereoscopic projection can be realized.

It is noted that the display device of this embodiment has a display screen which is frameless at both sides in the horizontal direction while has frames at both sides in a vertical direction. Namely, the display device is frameless at the left and right sides and has frames at the upper and lower sides. In this manner, the display device is assembled by means of bending structures at the left and right sides and frames at the upper and lower sides.

Here, as shown in FIG. 3, each second bending structure 21 of the display substrate 2 may comprise a side display area 22, so that the display device is capable of displaying at both sides, making it convenient for a user to control by touching. The side display area 22 can be located at an outer side of the frame sealant 3. In case the display device of this embodiment is applied to small electronic devices (e.g., mobile phone, handheld computers), functional buttons like volume buttons can be arranged at the side display area 22, so that the user can control the display device by touching the screen. In this way, the display device is multi-functional and more practical.

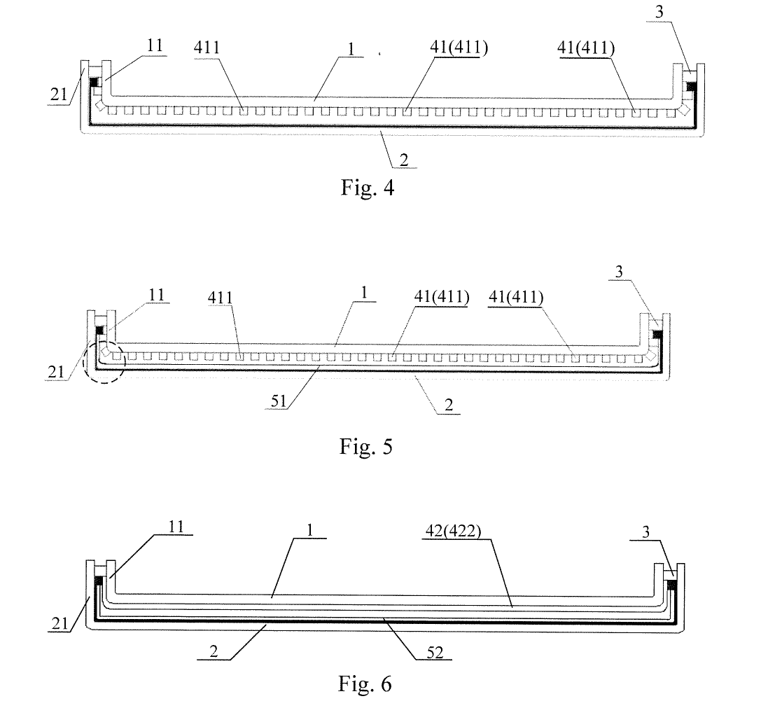

In particular, as shown in FIG. 4, a first light emitting layer 41 can be arranged on surfaces of the main body and the first bending structures 11 of the fixing substrate 1. The first light emitting layer 41 may comprise a plurality of color light emitting diodes 411. The color light emitting diodes 411 produce picture signals under control by a driver chip, and realize the display effects. The color light emitting diodes 411 can be red, green, and blue organic light emitting diodes (RGB-OLEDs). In particular, a plurality of RGB-OLEDs can be arranged uniformly on surface the main body and the first bending structures 11 of the fixing substrate 1. It is beneficial to improve picture effect at a display area AA of the display substrate 2 and picture effect at the side display area 22 of the second bending structures 21, so that pictures of the display area AA and the side display area 22 are coherent and transition smoothly. To this end, as shown in FIG. 5 by a dotted circle and further shown in FIG. 7, RGB-OLEDs can be directly arranged on corner portions 6 of the fixing substrate 1 and the first bending structures 11.

It is noted that the display substrate 2 can be a color film substrate, and the fixing substrate 1 can be an array substrate. A black matrix is arranged on an inner surface the main body and the second bending structures 21 of the display substrate 2, as shown in FIG. 4 by a black region. By subjecting to an exposure process, the black matrix can form light transmitting regions to realize the display function of the display device.

Further, to improve the overall color rendering performance of the (frameless) display device, as shown in FIG. 5, a first light filtering layer 51 can be arranged on surfaces the main body and the second bending structures 21 of to the display substrate 2 and cooperate with the first light emitting layer 41. The first light filtering layer 51 can be used to modify wavelength of light emitted from the first light emitting layer 41. In particular, the first light filtering layer 51 can be a RGB (red, green, and blue) color resistance layer, and can be arranged on the display substrate 2. In particular, a red element in the RGB color resistance is layer corresponds to a red diode in RGB-OLEDs in a one-to-one manner, a green element in the RGB color resistance layer corresponds to a green diode in RGB-OLEDs in a one-to-one manner, and a blue element in the RGB color resistance layer corresponds to a blue diode in RGB-OLEDs in a one-to-one manner. Due to a function of the RGB color resistance layer to filter light from RGB-OLEDs, wavelength of light emitted from RGB-OLEDs is modified by the RGB color resistance layer. Thereby, wavelength of light emitted from a light source is brought within an ideal range, and thus the display effect is improved.

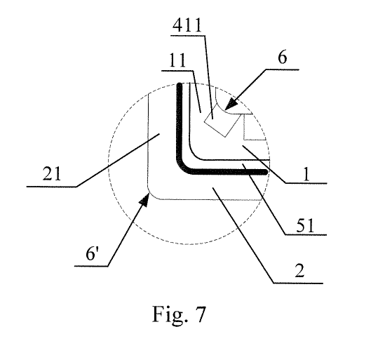

In practice, as shown in FIG. 6, in another display device of the present invention, a second light emitting layer 42 can be arranged on surfaces the main body and the first bending structures 11 of the fixing substrate 1. The second light emitting layer 42 may comprise a plurality of white light emitting diodes 422. In addition, a second light filtering layer 52 can be arranged on surfaces the main body and the second bending structures 21 of the display substrate 2 and cooperate with the second light emitting layer 42. In particular, the white light emitting diodes 422 can be common OLEDs (organic light emitting diodes). The second light filtering layer 52 can be a three-primary-color light filtering layer, i.e., a RGB color resistance layer, so as to display colored pictures.

Here, to avoid disconnection or damage at bending portions of the fixing substrate 1 and the display substrate 2 of the (frameless) display device, as shown in FIG. 7, the main body and the first bending structures 11 of the fixing substrate 1 can be are arranged to be perpendicular to each other, and corner portions 6 between the main body and the first bending structures 11 can be arc-shaped chamfers. Similarly, the main body and the second bending structures 21 of the display substrate 2 can be are arranged to be perpendicular to each other, and corner portions 6′ between the main body and the second bending structures 21 can also be arc-shaped chamfers. The arc-shaped chamfers effectively enable stable and smooth connections between the fixing substrate 1 and the first bending structures 11 (and/or between the display substrate 2 and the second bending structures 21), so that a blind angle is avoided and disconnection or damage is prevented.

On the premise that the subsequent assembly of the (frameless) display is device is not affected, the corner portions 6 between the main body and the first bending structures 11 of the fixing substrate 1 can also be cute angles. The corner portions 6 between the main body and the second bending structures 21 of the display substrate 2 can also be cute angles. Of course, cute angles of the corner portions 6, 6′ can be provided with arc-shaped connections, so as to avoid blind angles at connection sites, thus avoiding disconnection or damage and improving the frameless effect.

In practice, in the display device of the present invention, the fixing substrate 1 and the display substrate 2 can be glass substrates or plastic substrates of high transmittance to provide excellent display effect.

It is further noted that in the display device of the present invention, a display layer can not only adopt a self light emitting layer of OLED as mentioned above, but also adopt a liquid crystal layer. In particular, in case a liquid crystal light emitting layer is adopted, a U shaped electric field can be used to drive the liquid crystal layer for realizing the display effect, so as to provide uniform transition of brightness of a back light source at bending portions and stable distribution of electric field at bending portions. Besides, it is necessary to modify an additional electric field at bending portions, to avoid interference between electric fields at bending portions, which otherwise would affect a deflecting direction of liquid crystal. In this way, liquid crystal in the liquid crystal layer of the display device is prevented from deflecting in disorder. The U shaped electric field can adopt an ADS (Advanced Super Dimension Switch) or IPS (In-Plane Switching) electric field. It is noted that a vertical electric field like TN (Twisted Nematic) electric field should be avoided.

The display device of the present invention can be fabricated by a 3D printing technique, in which each layer is fabricated individually, subject to annealing as needed, and assembled into a display panel. The display panel is driven to display by means of a corresponding driver chip. Of course, alternatively, after the fixing substrate 1 and the display substrate 2 can be formed by a 3D printing technique, layers (like a black matrix, a light filtering layer, a light emitting layer) are printed on corresponding substrates, and the fixing substrate 1 and the display substrate 2 are assembled and sealed with the frame sealant 3 to form the display panel.

It will be apparent to those skilled in the art that various modifications and variations can be made in the present invention without departing form the spirit or scope of the invention. Thus, it is intended that the present invention cover the modifications and variations of this invention provided they come within the scope of the appended claims and their equivalents.

What is claimed is:

1. A display device, comprising a fixing substrate and a display substrate, characterized in that, the fixing substrate comprises a main body extending in a horizontal direction and first bending structures arranged at both sides of the main body, the display substrate comprises a main body extending in a horizontal direction and second bending structures arranged at both sides of the main body and matching the first bending structures, the second bending structures are located at outer sides of the first bending structures, and the fixing substrate and to the display substrate are engaged with each other and assembled in a sealed manner by means of the first and second bending structures.

2. The display device of claim 1, characterized in that, a frame sealant is arranged between the first and second bending structures.

3. The display device of claim 1, characterized in that, the second bending structures of the display substrate comprise a side display area.

4. The display device of claim 3, characterized in that, a first light emitting layer is arranged on surfaces of the main body and the first bending structures of the fixing substrate, and the first light emitting layer comprises a plurality of color light emitting diodes.

5. The display device of claim 4, characterized in that, a first light filtering layer is arranged on surfaces of the main body and the second bending structures of the display substrate, and the first light filtering layer cooperates with the first light emitting layer and is used to modify wavelength of light emitted from the first light emitting layer.

6. The display device of claim 3, characterized in that, a second light emitting layer is arranged on surfaces of the main body and the first bending structures of the fixing substrate, the second light emitting layer comprises a plurality of white light emitting diodes, and a second light filtering layer is arranged on surfaces of the main body and the second bending structures of the display substrate and cooperates with the second light emitting layer.

7. The display device of claim 1, characterized in that, the main body and the first bending structures of the fixing substrate are arranged to be perpendicular to each other, and corner portions between the main body and the first bending structures of the fixing substrate are arc-shaped chamfers;
the main body and the second bending structures of the display substrate are arranged to be perpendicular to each other, and corner portions between the main body and the second bending structures of the display substrate are arc-shaped chamfers.

8. The display device of claim 1, characterized in that, corner portions between the main body and the first bending structures of the fixing substrate are cute angles, and corner portions between the main body and the second bending structures of the display substrate are cute angles.

9. The display device of claim 1, characterized in that, the fixing substrate and the display substrate are glass substrates or plastic substrates of high transmittance.

10. The display device of claim 1, characterized in that, the fixing substrate is an array substrate, and the display substrate is a color film substrate.
